(19) United States
(12) Patent Application Publication
(10) Pub. No.: US 2024/0206115 A1
(43) Pub. Date: Jun. 20, 2024

(54) REVERSE BIAS FOR CORROSION PROTECTION IN LIQUID COOLING SYSTEMS

(71) Applicant: Cisco Technology, Inc., San Jose, CA (US)

(72) Inventors: Chun Chih CHEN, Hsinchu City (TW); Vipulkumar K. PATEL, Breinigsville, PA (US)

(21) Appl. No.: 18/067,550

(22) Filed: Dec. 16, 2022

(51) Int. Cl. H05K 7/20; G01N 17/02

(52) U.S. Cl. CPC H05K 7/20263; G01N 17/02; H05K 7/20272; H05K 7/20509

(57) ABSTRACT

A liquid cooling system with a reverse bias system is described. The reverse bias system serves several functions, including monitoring a corrosion in the liquid cooling system as well as providing a reverse bias voltage to reduce a galvanic current in the system and to prevent corrosion in the liquid cooling system. The reverse bias system in the liquid cooling system allows for heterogeneous usage of metallic materials, which results in a lighter weight and easier to fabricate liquid cooling system.

### TECHNICAL FIELD

Embodiments presented in this disclosure generally relate to providing cooling and heat mitigation via liquid cooling systems in computer/electrical systems such as data center servers, switches, and storage systems. More specifically, the liquid cooling systems described herein include a reverse bias system which applies an external reverse bias voltage in the liquid cooling system to reduce a galvanic current and prevent corrosion in the liquid cooling system.

### BACKGROUND

As computer systems and the associated electronic devices increase in power and complexity, the heat output of these systems also increases. While traditional air flow based cooling systems provide some levels of cooling, liquid cooling systems are increasingly found to provide more direct and efficient cooling paradigms for high powered and high heat producing electronic devices. While development in liquid cooling systems has improved, the related efficiencies and costs of installing and maintaining liquid cooling systems remains challenging.

For example, liquid cooling systems are typically more expensive in time and resource usage compared to the traditional airflow systems. One of the primary causes of the time and resource costs in liquid cooling systems relates to ensuring that liquid coolant in the systems is at appropriate levels in the system and not leaking from the system. Much of this required maintenance and need for liquid replacement and system inspection is due to corrosion that occurs in the liquid cooling systems. Reducing or preventing corrosion in the liquid cooling systems remains a challenge.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1A illustrates a closed loop liquid cooling system, according to one embodiment.

FIG. 1B illustrates a perspective view of a closed loop liquid cooling system, according to one embodiment.

FIG. 2 illustrates on open loop liquid cooling system, according to one embodiment.

FIG. 3 illustrates a liquid cooling system with a reverse bias system, according to one embodiment.

FIG. 4A illustrates a reduction of galvanic current in liquid coolants in a liquid cooling system, according to one embodiment.

FIG. 4B illustrates a reduction corrosion in a liquid cooling system, according to one embodiment.

FIG. 5 illustrates a circuit diagram of a reverse bias system, according to one embodiment.

FIG. 6 is a flowchart for applying a reverse bias in a liquid cooling system, according to one embodiment.

FIG. 7 illustrates a block diagram of a reverse bias system, according to one embodiment.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One example embodiment includes a method. The method includes measuring a galvanic current between a first component and a second component in a liquid cooling system, determining, based on the galvanic current and a corrosion model for the liquid cooling system, a reverse bias voltage to prevent corrosion in the liquid cooling system, and applying the reverse bias voltage in the liquid cooling system. Other embodiments of this aspect include corresponding computer systems, apparatus, and computer programs recorded on one or more computer storage devices, each configured to perform the actions of the methods.

One example embodiment includes a system. The system includes a processor, and a memory may include instructions which, when executed on the processor, performs an operation. The operation includes: measuring a galvanic current between a first component and a second component in a liquid cooling system, determining, based on the galvanic current and a corrosion model for the liquid cooling system, a reverse bias voltage to prevent corrosion in the liquid cooling system, and applying the reverse bias voltage in the liquid cooling system. Other embodiments of this aspect include corresponding computer systems, apparatus, and computer programs recorded on one or more computer storage devices, each configured to perform the actions of the methods.

One example embodiment includes a liquid cooling system. The liquid cooling system includes a first heat exchange component of a first material, a second heat exchange component of a second material, a first pipe between the first heat exchange component and the second heat exchange component, a first electrical contact on a first end of the first pipe, a second electrical contact on a second end of the first pipe, and a reverse bias system, The reverse bias system includes: an external bias circuit electrically connected to the first electrical contact and the second electrical contact a processor, and a memory may include instructions which, when executed on the processor, performs an operation. The operation includes: measuring a galvanic current between the first electrical contact and the second electrical contact, determining, based on the galvanic current and a corrosion model for the liquid cooling system of the liquid cooling system, a reverse bias voltage to prevent corrosion in the liquid cooling system, and applying the reverse bias voltage via the external bias circuit. Other embodiments of this aspect include corresponding computer systems, apparatus, and computer programs recorded on one or more computer storage devices, each configured to perform the actions of the methods.

### EXAMPLE EMBODIMENTS

As described above, liquid cooling systems provide effective cooling to high heat producing electronic devices. However, in general liquid cooling systems have several intrinsic problems related to the corrosion of the various components in the system over time.

Some solutions to counteract the corrosion have been implemented to limited success in liquid cooling systems. For example, a corrosion inhibitor may be added to the liquid coolant to slow corrosion; however, these corrosion inhibitors and the related thermal conductivity of the liquid coolant in liquid cooling systems often degrades over time. This degradation may be caused by a degradation of corrosion inhibitors in liquid coolants, temperature induced degradation, or by oxidation in the liquid. This degradation, in turn, requires the liquid to be refilled or replaced frequently, which increases maintenance costs of the liquid cooling system.

In some cases, corrosion is most significant in liquid cooling systems with differing materials due to galvanic corrosion. For example, a cold plate and radiator with different metals, such as copper and aluminum, may experience large amounts of galvanic corrosion. Homogenous systems, such as copper only based liquid cooling systems avoid this problem of galvanic corrosion, but may have greater fabrication costs, relatively heavy in weight, and suffer from low production yields in manufacturing.

Other example solutions include the use of an insulator plate or washer to prevent the contact between two different metals in the systems. While this solution prevents direct galvanic reactions between the metals, it does not stop corrosion reactions in a liquid phase between the coolant and metal surfaces. Another solution includes using anodized metals, such as anodized aluminum; however the coolant and dissolved oxygen may still penetrate an aluminum oxide layer and corrode an aluminum surface in the liquid cooling system.

The systems and methods described herein provide for a liquid cooling system with a reverse bias system. The reverse bias system serves several functions, including monitoring a corrosion in the liquid cooling system as well as providing a reverse bias voltage to prevent corrosion in the liquid cooling system. The reverse bias system in the liquid cooling system allows for heterogeneous usage of metallic materials, which results in a lighter weight and easier to fabricate liquid cooling system. The liquid cooling system and the associated reverse bias system are discussed in more detail in relation to the Figures below.

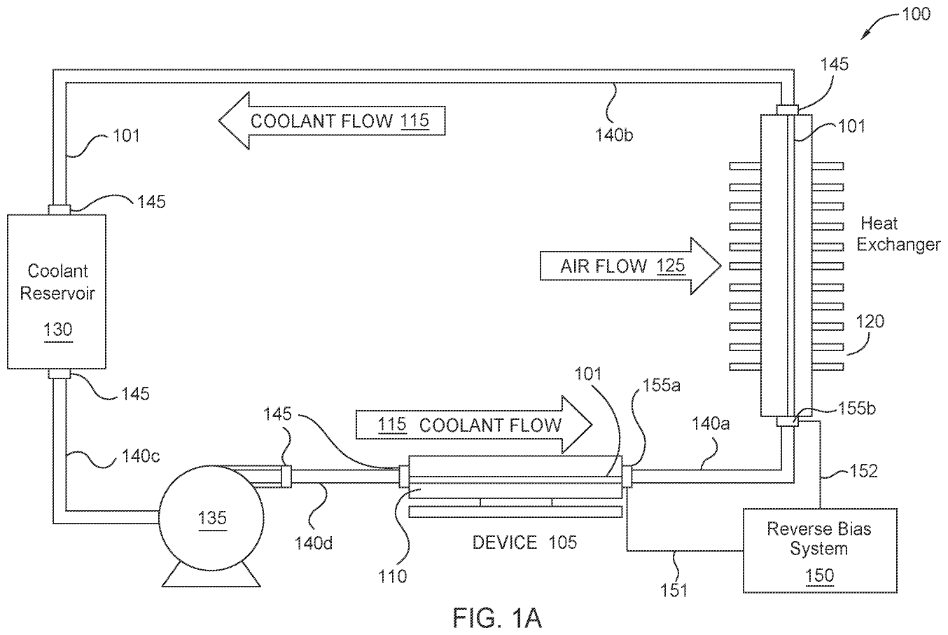

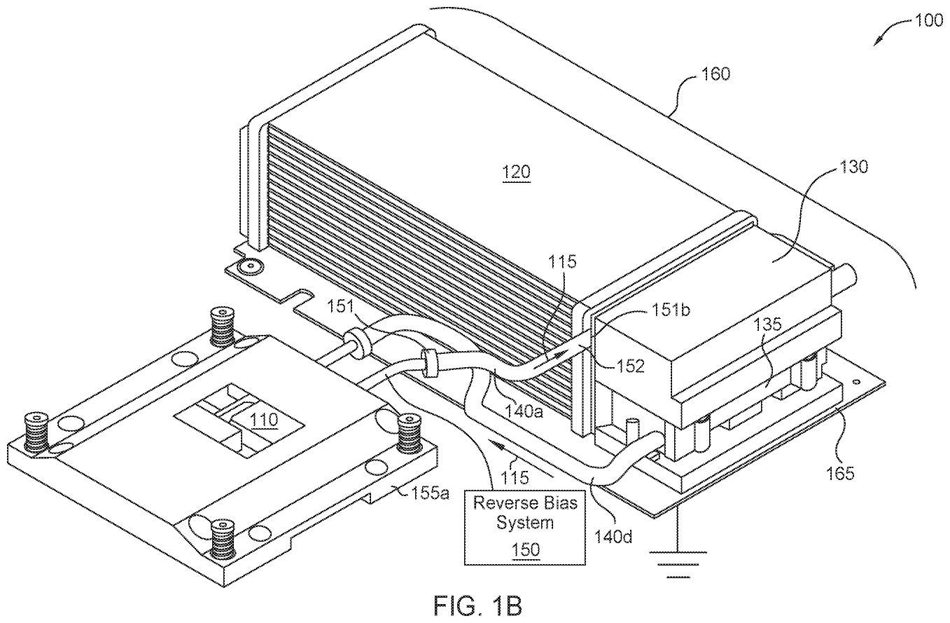

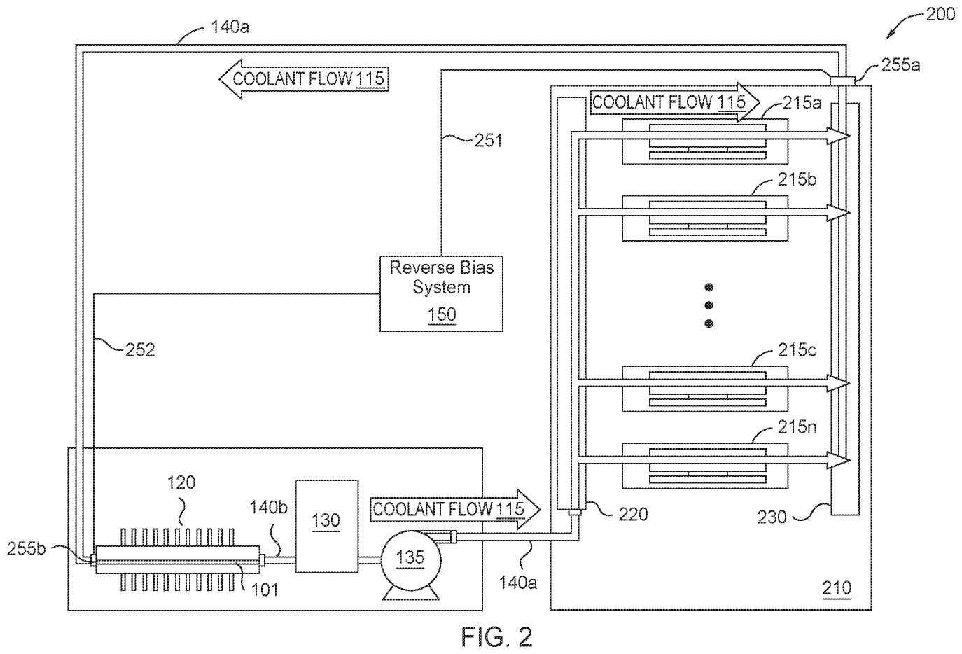

FIG. 1A illustrates a closed loop liquid cooling system, system 100, and FIG. 1B illustrates a perspective view of the system, according embodiments described herein. The system 100 is referred to a closed loop system since a liquid coolant 101 flows through each component of the system 100 in a closed loop. The embodiments described herein do not require that the various liquid cooling systems are arranged in closed loops. (For example, an open loop liquid cooling system is described in more detail in relation to FIG. 2.) The system 100 provides cooling to various electronic components in the system by circulating the liquid coolant 101 from heat producing electronic components to heat radiating components.

For example, the system 100 includes device 105 which produces heat. In some examples, the device is in integrated circuit (IC) chip (e.g., an application-specific integrated circuit (ASIC) chip) or other type of electronic/heat producing device which produces heat at a level that requires external cooling. For example, the device 105 may produce an amount of heat that would degrade a performance of the device 105 without heat mitigation via a cooling system associated with the device 105.

To provide heat mitigation or cooling to the device 105, the system 100 includes component 110 attached to the device 105 or otherwise positioned to provide heat exchange between the device 105 and the liquid coolant 101. The component 110 may include any type of heat exchanger which provides heat exchange and cooling to the device 105. In some examples, the component 110 is a cold plate which includes tubing embedded in a heat conductive material in the component 110, where the liquid coolant 101 flows through the tubing and absorbs heat from the device 105 via the heat conductive material. In some examples, the liquid coolant 101 flows as heated coolant from the component 110 to a component 120 where the liquid coolant 101 exchanges or radiates the heat absorbed at the component 110 into the component 120.

The component 120 may include any type of heat exchanger or radiator which provides for heat exchange/absorption from heated liquid coolant. For example, the component 120 may include a radiator, such as an air cooled aluminum radiator, which radiates heat from the component 120 to an airflow 125 which flows across and through various subcomponents of the component 120 (e.g., radiator fins etc.). The component 120 provides the liquid coolant 101, as a cooled coolant back to recirculation components of the system 100. For example, the liquid coolant 101 flows into a coolant reservoir 130 and is recirculated into the component 110 by a coolant pump system such as a coolant pump 135. The coolant pump 135 provides the liquid coolant 101 along the coolant flow 115 from the component 110 to the component 120, the coolant reservoir 130 and any other additional components typical to a liquid cooling system.

The liquid coolant 101 flows between the various components via conduits, tubing, or pipes such as pipe 140a, pipe 140b, pipe 140c, and pipe 140d. In some examples, the pipes 140a-140d are plastic piping or piping formed from other inert or non-reactive and non-conductive materials. The pipes are connected to the various components via fittings 145, fitting 155a, and fitting 155b. For example, the fitting 155a connects the pipe 140a to the component 110 and the fitting 155b connects the pipe 140a to the component 120. In some examples, the fittings 145, 155a, and 155b are formed from metallic or conductive materials, such that the fitting serve as electrical contacts as described in more detail herein.

While shown in FIG. 1A in a circular arrangement, the various components of system 100 may be positioned in various arrangements in relation to the other components of the system. Additionally, the components of the system 100 may be collocated on a structure (e.g., located on a single chassis or other base structure) or may be located at different locations. For example as shown in FIG. 1B, the component 120, coolant reservoir 130 and coolant pump 135 may be collocated as a group 160 where the components are mounted on a chassis 165. The group 160 and chassis 165 may be remote from the component 110 (and device 105 not shown in FIG. 1B). The pipes 140a and 140d provide for liquid connections between the group 160 and the component 110. Additionally, a reverse bias system 150 may be collocated with other components of the system 100 or remote from both the group 160 and the component 110. In some examples, the reverse bias system 150 is positioned on a chassis or base structure independent of either the chassis 165 or component 110. The reverse bias system 150 is connected to the system 100 via connections 151 and 152. The reverse bias system 150 provides for both monitoring and detection of corrosion in a liquid cooling system and for applying an external reverse bias voltage to prevent corrosion in the liquid cooling system, as described in more detail herein.

In another example, a liquid cooling system provides cooling to an open loop system, such as system 200 in FIG. 2. The system 200 includes the liquid coolant 101, the component 120, coolant reservoir 130, and coolant pump 135 which pumps the liquid coolant 101 through the system 200 along the coolant flow 115. In the system 200, cooling heat exchanges is provided to a plurality of heat producing electronic devices via a manifold system 210. The manifold system 210 includes a supply manifold 220 which provides liquid coolant received via the pipe 140 to arrangements 215a-215n. In some examples, each of the arrangements 215a-215n includes a component and a device (e.g., the component 110 and the device 105). In some examples, the liquid coolant 101 flows from the supply manifold 220 through a plurality of copper cold plates (or other copper heat exchangers) in the arrangements 215a-215n and heated liquid coolant 101 flows into the return manifold 230. The heated liquid coolant flows from the return manifold 230 the component 120 via the pipe 140a. The system 200 also includes the reverse bias system 150, where the reverse bias system 150 is connected to fitting 255a and fitting 255b via connections 251 and 252 respectively. The arrangement of system 200 in FIG. 2 is shown in a circular arrangement; however, the various components of the system 200 may be collocated or positioned in remote locations similar to system 100 in FIG. 1B.

As described above, the liquid cooling systems, systems 100 and 200, are subject to various levels of corrosion which often causes several issues in the systems. For example with reference back to FIG. 1A, the liquid coolant 101 may cause galvanic and other corrosion in any metallic components with which the coolant contacts or interacts. These corrosion sources may include any of component 110, 120, coolant reservoir 130, and the coolant pump 135. In some examples, as the system 100 corrodes, the corroded materials collect in the liquid coolant 101 which in turn lowers a heat exchange efficiency and thermal performance of the liquid coolant 101. For example, the liquid coolant 101 with large amounts of corroded material in suspended in the liquid will not exchange heat with the component 110 and component 120 at a same efficiency as a liquid coolant 101 without corroded materials. Additionally, corroded materials may cause clogs, blockages, or other reduced flow issues such that the liquid coolant 101 along the coolant flow 115 requires a higher energy output from the coolant pump 135 and provides lower amounts of exchange between the component 110, component 120 and the liquid coolant 101.

In some examples, corrosion in the system 100 also degrades the structural integrity of the metallic components, including component 110, component 120, and the fittings 145, 155a, and 155b. This degradation may cause the various components to decrease in performance. For example, the components 110 and 120 may not exchange heat as efficiently as designed. Additionally, the structural degradation may cause leaks to form in the system 100. For example, leaks may form in any of the components 110 and 120 and the fittings 145, 155a, and 155b. Leaks of the liquid coolant 101 require for the leaks to be repaired and for coolant to be refilled which increases the overall maintenance costs of the system 100.

In order to prevent or reduce corrosion in the system 100, the system may include several corrosion mitigation measures. For example, the system 100 may include metallic interactions with the liquid coolant 101. For example, the component 110, the component 120, and the various fittings may all be formed from a single metallic material, such as copper. In example where all of metallic interactions with the liquid coolant are copper, corrosion in the system 100 is reduced; however, copper is relatively heavy compared to other suitable materials (e.g., aluminum). This increased weight in limits the feasibility of fabricating and installing the system 100.

In some examples, lighter weight heterogeneous materials may be used. For example, a mixture of copper components and aluminum components may be used in the system 100, which reduces the weight of the system 100. In some examples, the various aluminum components may include protective layers, such as an aluminum oxide layer between the liquid coolant 101 and the components themselves. For example, the component 120 as an aluminum radiator includes an aluminum oxide layer between the liquid coolant 101 and an aluminum body of the radiator. In some examples, the protective layers reduce corrosion in the system, but corrosion may still occur through protective layers and the thermal conductivity of the protective layers is lower than the surrounding materials.

Another example corrosion resistance measure includes increasing a resistance of the liquid coolant 101, such that corrosion via galvanic reactions is reduced. In some examples, corrosion inhibitors reduce corrosion, but increases maintenance costs and requires frequent liquid exchange or refill in order to keep the corrosion inhibitor at optimum levels in the liquid coolant 101. While each of the above solutions provide some measure of corrosion preventing in the system 100, corrosion may still be present in the system 100.

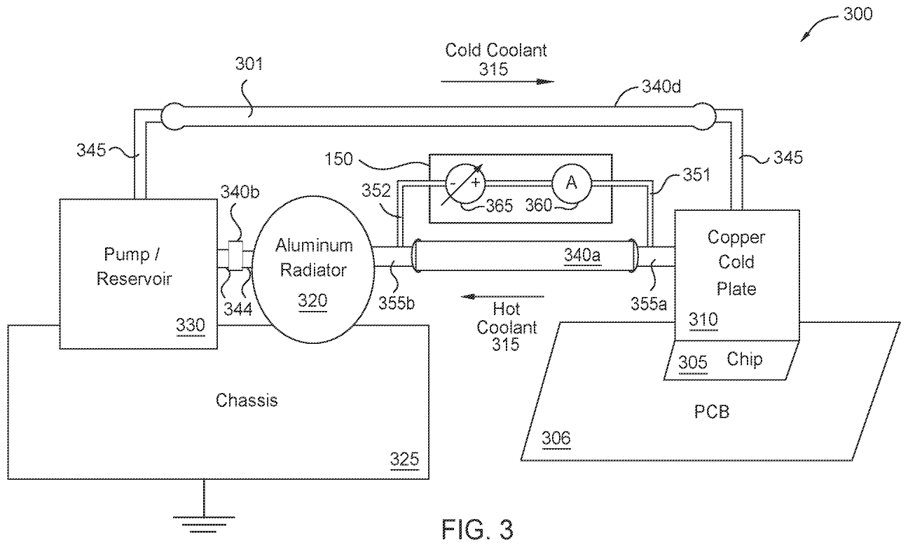

In order to provide efficient and effective corrosion prevention in the system 100, the system 100 (and the system 200 in FIG. 2) includes a reverse bias system such as reverse bias system 150. In some examples, the reverse bias system 150 includes connection 151 connected to the fitting 155a and connection 152 connected to the fitting 155b. As described in more detail herein, the reverse bias system 150 provides for corrosion prevention in the system 100 by applying an external reverse bias via the connections 151 and 152. The determination and application of the reverse bias voltage is described in more detail herein in relation to FIGS. 3-6.

FIG. 3 illustrates a liquid cooling system with a reverse bias system, according to one embodiment. System 300 is a liquid cooling system similar to the systems 100 and 200 described above in relation to FIGS. 1A-B and 2. The system 300 includes the reverse bias system 150 to prevent corrosion in the system 300. The system includes a coolant pump system such as pump/reservoir 330 and aluminum radiator 320 mounted on a grounded chassis 325. In some examples, the aluminum radiator 320 is an air cooled aluminum radiator. The pump/reservoir 330 receives a coolant 301 from the aluminum radiator 320 via a pipe 340b connected to each respective component via fittings 344. The pump/reservoir 330 provides the coolant 301 in a cold state to copper cold plate 310 via a pipe 340d. The pipe 340d is connected to the pump system and the copper cold plate 310 via fittings 345.

The copper cold plate 310 provides heat exchange/cooling to a chip 305 mounted on a printed circuit board 306. As the coolant 301 flows along direction 315 into the copper cold plate 310, the coolant is heated such that the coolant 301 flows from the copper cold plate 310 to the aluminum radiator 320 via a pipe 340a. The pipe 340a is connected to the copper cold plate 310 via fitting 355a and aluminum radiator 320 via fitting 355b. The reverse bias system 150 is electronically connected to the system 300 via connections 351 and 352. For example, the connection 351 connects the reverse bias system 150 to the fitting 355a and the connection 352 connects the reverse bias system 150 to the fitting 355b.

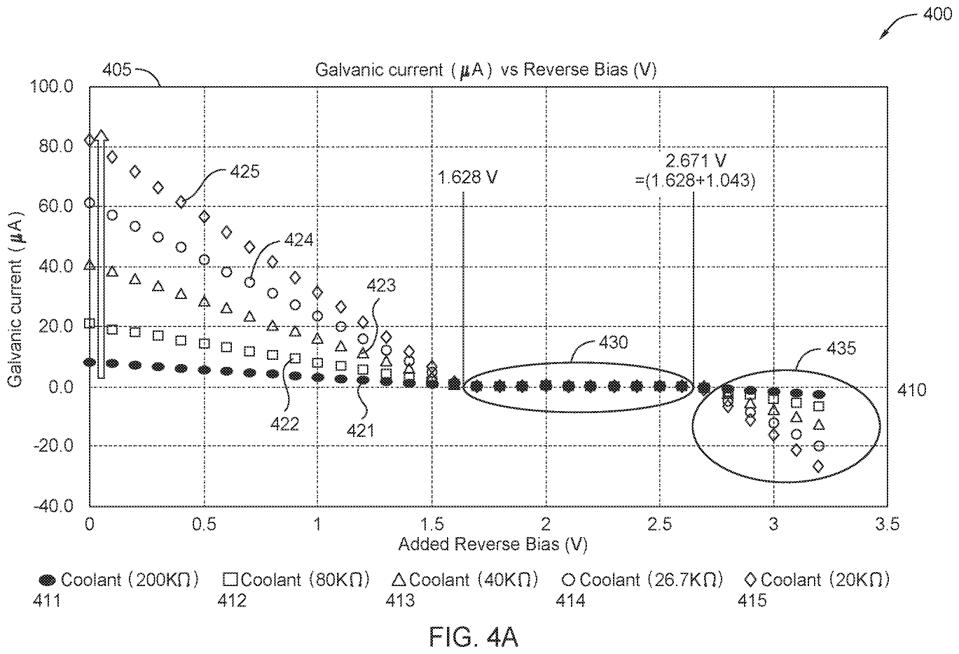

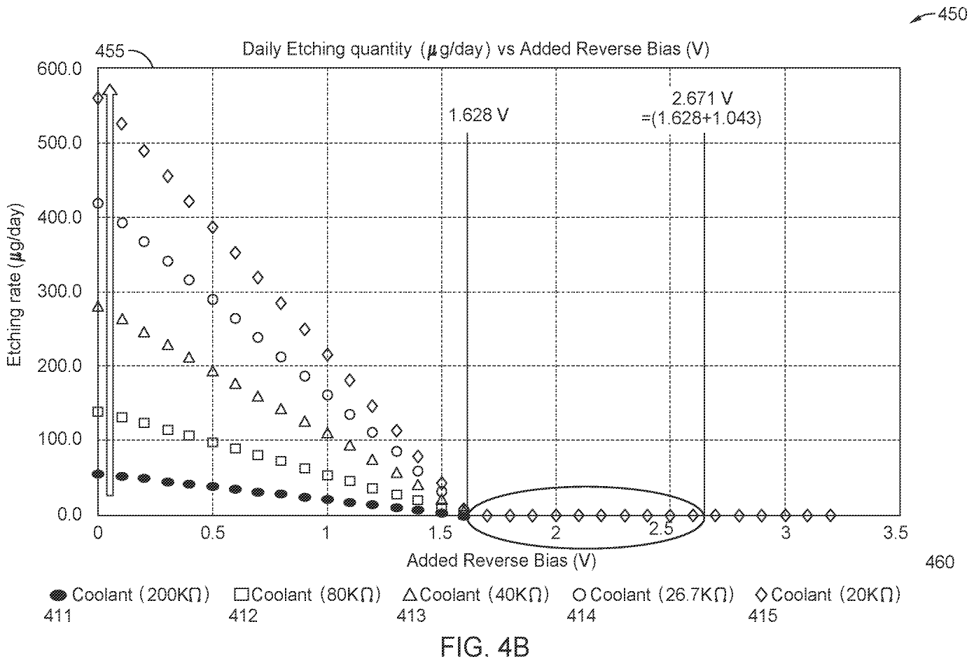

As discussed above, the heterogeneous usage of metal materials such as aluminum and copper in the system 300 causes galvanic corrosion in the system 300. Galvanic corrosion causes a galvanic current in the system 300 and may be calculated or estimated using the Nernst equation to define the thermodynamic relationship between a galvanic current and the related corrosion/etching in the system. In some examples, as temperature of the system 300 increases during operation, the galvanic corrosion also increases. The reverse bias system 150 includes a current meter 360 to measure the galvanic current and a reverse bias source 365 to apply an external reverse bias voltage to the system 300. In some examples, the current meter 360 measures the galvanic current between a first component and a second component in a liquid cooling system. For example, the current meter 360 is positioned to measure the galvanic current across the fittings 355a and 355b between the copper cold plate 310 and the aluminum radiator 320. The reverse bias system 150 then uses the galvanic current to apply the reverse bias voltage via the reverse bias source 365 to reduce corrosion as illustrated in FIGS. 4A-B.

In some examples, the spontaneous galvanic current in the system 300 is related to material properties of the coolant 301 as shown in chart 400 in FIG. 4A. The chart 400 illustrates galvanic current and applied reverse bias for a plurality of coolant types. The examples shown in FIGS. 4A-4B include example values for coolant solutions, galvanic currents, and reverse bias. Additional considerations may be included in the determination of galvanic current and an added reverse bias. For example, oxidation or corrosion of other materials in the system 300 may also be considered in the determination of the galvanic current and added reverse bias. For example, copper oxidation may also be considered in the galvanic calculations such that the galvanic current and subsequent reverse bias are in a range of approximately 0.6V to 0.8V.

Returning back to FIG. 4A, axis 405 illustrates galvanic current in microamperes (μA) in a system based on a liquid conductivity of a respective coolant. Axis 410 illustrates an applied voltage in volts (V) applied by the reverse bias source 365. For example, various coolants may have differing associated coolant resistances in Ohms (Ω). For example, a coolant 411 has a coolant resistance of 200KΩ, coolants 412, 413, 414, and 415 each have respective liquid resistances of 80 KΩ, 40 KΩ, 26.7 KΩ, and 20 KΩ. Trend lines 421-425 are associated with the respective coolants 411-415 and illustrate that coolants with higher comparative liquid resistances produce a lower galvanic current.

For example, the coolant with a relatively low resistance causes a galvanic current of approximately 80 μA in the system 300. As the reverse bias source 365 applies a reverse voltage, the galvanic current of the coolant 415 reduces from 80 μA at 0 V to 0 μA when approximately 1.68 V is applied. In a voltage region 430, (e.g., between applied voltages of 1.628V to 2.671V), the galvanic current remains at 0 μA and in a voltage region 435 (e.g., applied voltage greater than 2.671), the respective coolants electrolyze and the respective galvanic current is reversed or goes negative. In some examples, the reverse bias voltage is limited to low voltages, (a lowest voltage that provides a zero galvanic current) to prevent oxidation or corrosion in other components, such as copper components in the system 300.

Chart 450 illustrates a reduction of corrosion in an etching rate per day based on the applied voltage in the system. Axis 455 illustrates an etching rate per day in the system 300 in micro-grams per day (μg/day). Axis 460 illustrates the applied voltage in volts (V) applied by the reverse bias source 365. Trend lines 471-475 are associated with the respective coolants 411-415. For example, the coolant with a relatively low resistance causes an etching rate of approximately 600 μg/day in the system 300. As the reverse bias source 365 applies a reverse voltage, the etching rate of the coolant 415 reduces from 600 μg at 0 V to 0 μg when approximately 1.68 V is applied. In the voltage regions 430 and 435, (e.g., between applied voltages above 1.628V), the etching rate remains at 0 μg.

Returning back to FIG. 3, the reverse bias system 150 determines, based on a corrosion model for the liquid cooling system and the galvanic current measured by the current meter 360, a corrosion status of the liquid cooling system at a first time. In some examples, the corrosion status includes an amount of corrosion present in the system based on the material properties of the coolant and the measure galvanic current. The reverse bias system 150, using the corrosion status and the galvanic current, determines a reverse bias voltage to prevent corrosion in the liquid cooling system. For example, the reverse bias system 150 determines a reverse bias voltage that would bring the corrosion rate to 0 μg/day.

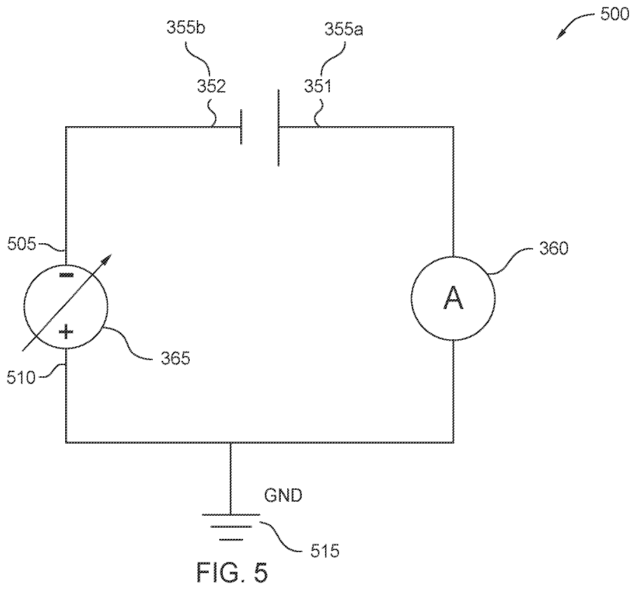

The reverse bias system 150, including the reverse bias source 365 applies the determined reverse bias voltage in the liquid cooling system. In some examples, a negative electrode of the reverse bias source 365 is connected to the fitting 355b and a positive node is connected to the fitting 355a as shown in the circuit diagram in FIG. 5. Circuit 500 is an external bias circuit and includes an I-probe with current meter 360 and the reverse bias source 365. The circuit 500 also includes a ground 515. The reverse bias source 365 includes a positive electrode 510 and a negative electrode 505. The negative electrode 505 is electrically connected to the fitting 355b via the connection 352. The positive electrode 510 is electrically connected to the fitting 355a via the connection 351.

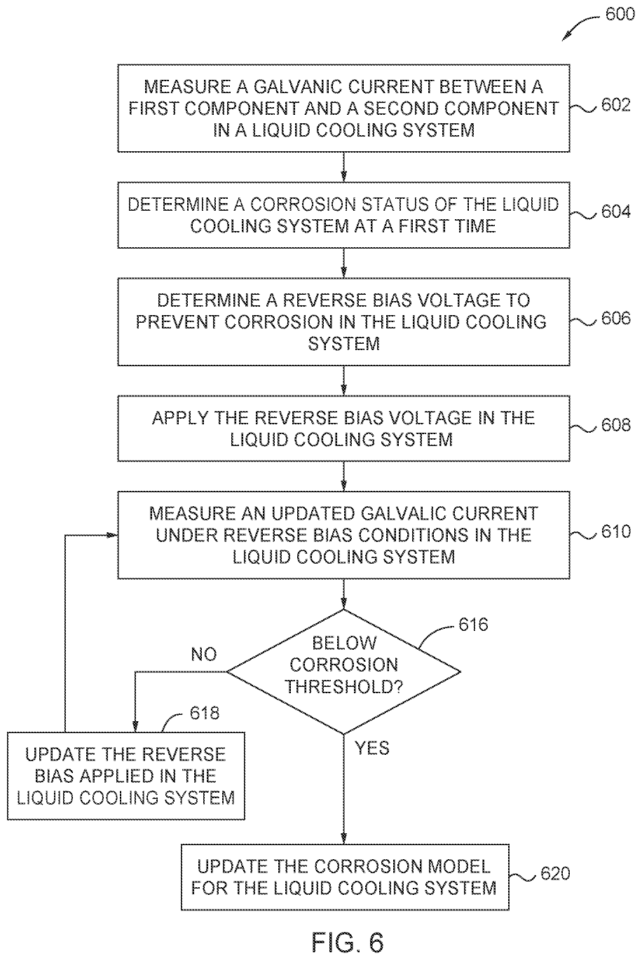

In some examples, the connection of the negative electrode 505 of external bias to the aluminum radiator 320 (via connection 352) and the positive electrode to copper cold plate 310 allows for the external bias to be applied in the system 300 without the need of an external inert dummy metal as a counter electrode in traditional cathode protection systems. Additionally, the reverse bias system 150 provides the reverse bias between 1.63V to 2.67V to diminish the galvanic reaction with zero galvanic current. In another example, the reverse bias system 150 provides the reverse bias between 0.6V and 0.8V to diminish the galvanic reaction with zero galvanic current and to prevent corrosion in other elements such as copper components in the system 300. In contrast, traditional cathode protection requires 20V to 100V and produces significant current on components in the system 300. These high voltages may cause water electrolysis, copper oxidation, and other electrochemical reactions which may reduce the thermal performance as well as the lifetime of the coolant 301. The determination and application of the reverse bias voltage is discussed in more detail in relation to FIG. 6.

FIG. 6 is a flowchart for applying a reverse bias in a liquid cooling system, according to one embodiment. Method 600 begins at block 602 where the reverse bias system 150 measures a galvanic current between a first heat exchange component and a second heat exchange component in a liquid cooling system. In some examples, the components are heterogeneous components, where the first component is a copper heat exchanger and the second component is an aluminum heat exchanger. In some examples, a negative electrode associated with a reverse bias voltage source is electrically connected to the aluminum heat exchanger and a positive electrode associated with a reverse bias voltage is connected to the copper heat exchanger.

At block 604, the reverse bias system 150 determines, based on a corrosion model for the liquid cooling system and the galvanic current, a corrosion status of the liquid cooling system at a first time. In some examples, the corrosion model includes a coolant equivalent resistance for a liquid in the liquid cooling system, and historically applied reverse biases in the liquid cooling system. The corrosion model may include corrosion monitoring data collected for the system 300 or other similar systems where the corrosion monitoring data is based on real world observations of corrosion in liquid heating systems versus theoretical or mathematical expectations for the system 300.

At block 606, the reverse bias system 150 determines, based on the corrosion status of the liquid cooling system, a reverse bias voltage to prevent corrosion in the liquid cooling system. In some examples, the reverse bias system 150 determines the reverse bias voltage based on the coolant equivalent resistance and the reverse bias voltage is a voltage to counteract the galvanic current. For example, the reverse bias system 150 determines a voltage that would cause the observed galvanic current in the system 300 to drop to 0 μA. In some examples, the reverse bias system 150 also updates the reverse bias voltage based on the historically applied reverse biases. For example, when the system 300 has experienced corrosion at a given applied reverse bias voltage, the reverse bias system 150 may increase the reverse bias voltage beyond a given level based solely on the measured galvanic current in order to further reduce corrosion.

At block 608, the reverse bias system 150 applies the reverse bias voltage in the liquid cooling system. In some examples, the reverse bias system 150 applies the reverse bias voltage via electrical contacts in the liquid cooling system, where the applied bias voltage reduces the galvanic current to prevent corrosion in the liquid cooling system. In some examples, the reverse bias system 150 applies the reverse bias voltage via electrical contacts in the liquid cooling system, where the applied bias voltage reduces the galvanic current to prevent corrosion in the liquid cooling system. For example, as shown in FIG. 4B, galvanic corrosion drops from a given etching rate to 0 μg/day.

At block 610, the reverse bias system 150 measures an updated galvanic current under reverse bias conditions in the liquid cooling system. For example, the reverse bias system 150 measures the updated galvanic current on an ongoing basis to determine whether an applied reverse bias voltage is effective at preventing corrosion in the system.

At block 616, the reverse bias system 150 compares the updated galvanic current to a corrosion threshold. In some examples, the corrosion threshold is 1 microampere. For example, when the update galvanic current is above 0 or above a threshold such as the 1 microampere, the applied voltage should be increased in the system 300.

In an example where the galvanic current is above a corrosion threshold, method 600 proceeds to block 618 where the reverse bias system 150 updates the reverse bias applied in the liquid cooling system (similar to block 606) and returns to block 610 to measure the galvanic current under reverse bias conditions.

In an example where the galvanic current is below the corrosion threshold, method 600 proceeds to block 620 where the reverse bias system 150 updates the corrosion model for the liquid cooling system with an indication of the galvanic current, the reverse bias voltage, and a time of reverse bias application. In some examples, the corrosion model is used by the reverse bias system 150 to continue monitoring the system 300 for corrosion at block 622. For example, the reverse bias system 150 continuously monitors the galvanic current and a corrosion level in the liquid cooling system over a useful life of the system 300, according to the methods of blocks 602-620. In some examples, as temperatures of the system 300 change during operation, the galvanic current and corrosion also changes. For example, a galvanic current may occur in the system within a range during a given operating period (e.g., over a day), thus the reverse bias system 150 monitors the galvanic current and adjusts the reverse bias voltage to provide a zero galvanic current at any given moment during operation of the system 300.

In some examples, the reverse bias system 150 provides measured galvanic currents, corrosion levels, and applied voltages as telemetry data to an external monitoring system and/or users for review of the measured data. For example, the reverse bias system 150 may provide information on needed maintenance (e.g. liquid exchange, etc.) for the system 300 and/or the reverse bias system 150. Additionally, the corrosion model may be provided to one or more users with an indication of the corrosion status of the system 300 in order to determine any maintenance or updates needed in the system.

As described above, the reverse bias system 150 provides for a reduction of the galvanic current and associated galvanic corrosions in the system 300 such that the life liquid coolant in the system and the other components of the system are increased while also reducing maintenance and fabrication costs compared to legacy liquid cooling systems.

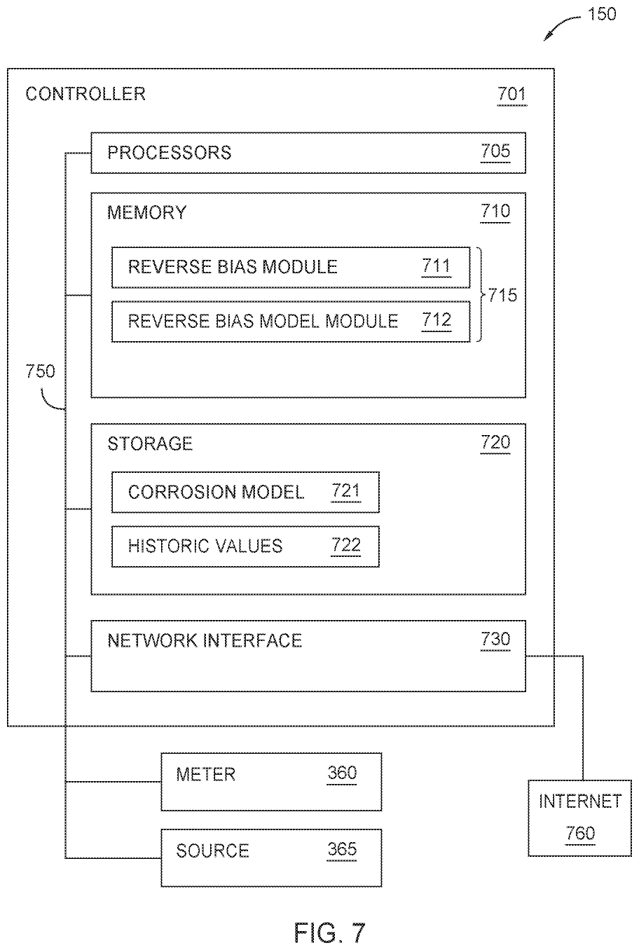

FIG. 7 illustrates a block diagram of a reverse bias system, according to one embodiment. The reverse bias system 150 may include a controller 701 embodied as computer or other electronic device which executes the functions of the reverse bias system 150 shown in FIGS. 1A, 1B, 2, 3, and 5, and perform the methods, including method 600 described herein. The controller 701 is shown in the form of a general-purpose computing device. The components of controller 701 may include, but are not limited to, one or more processing units or processors 705, a system memory 710, a storage system 720, a bus 750 that couples various system components including the system memory 710 and storage system 720 to processors 705, along with current meter 360, reverse bias source 365, and along with an external network interface 730. The external network interface 730 is connected to an external network such as the internet 760. In some embodiments, the reverse bias system 150 is distributed and includes a plurality of discrete computing devices that are connected through wired or wireless networking.

System memory 710 may include a plurality of program modules 715 for performing various functions related applying an external reverse bias voltage, described herein. The program modules 715 generally include program code that is executable by one or more of the processors 705. As shown, program modules 715 include a reverse bias module 711 and a reverse bias model module 712. In some examples, the program modules 715 may be distributed and/or cloud based applications/modules. Additionally, storage system 720 may include media for a corrosion model 721 and historical values 722, and other information. The information stored in storage system 720 may be updated and accessed by the program modules 715 described herein.

Additionally various computing components may be included to perform the methods described herein. For example, bus 750 represents one or more of any of several types of bus structures, including a memory bus or memory controller, a peripheral bus, an accelerated graphics port, and a processor or local bus using any of a variety of bus architectures. In some examples, such architectures may include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Further, controller 701 typically includes a variety of computer system readable media. Such media may be any available media that is accessible by controller 701, and it includes both volatile and non-volatile media, removable and non-removable media.

System memory 710 can include computer system readable media in the form of volatile memory, such as random access memory (RAM) and/or cache memory. Controller 701 may further include other removable/non-removable, volatile/non-volatile computer system storage media. In some examples, storage system 720 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 750 by one or more data media interfaces.

As depicted and described above, system memory 710 may include at least one program product having a set (e.g., at least one) of program modules 715 that are configured to carry out the functions of embodiments of the invention. Controller 701 may further include other removable/non-removable volatile/non-volatile computer system storage media. In some examples, storage system 720 may be included as part of system memory 710 and may typically provide a non-volatile memory for the networked computing devices, and may include one or more different storage elements such as Flash memory, a hard disk drive, a solid state drive, an optical storage device, and/or a magnetic storage device.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

As will be appreciated by one skilled in the art, the embodiments disclosed herein may be embodied as a system, method or computer program product.

Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, embodiments may take the form of a computer program product embodied in one or more computer readable medium(s) having computer readable program code embodied thereon.

Program code embodied on a computer readable medium may be transmitted using any appropriate medium, including but not limited to wireless, wireline, optical fiber cable, RF, etc., or any suitable combination of the foregoing.

Computer program code for carrying out operations for embodiments of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described herein with reference to flowchart illustrations and/or block diagrams of methods, apparatuses (systems), and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the block(s) of the flowchart illustrations and/or block diagrams.

These computer program instructions may also be stored in a computer readable medium that can direct a computer, other programmable data processing apparatus, or other device to function in a particular manner, such that the instructions stored in the computer readable medium produce an article of manufacture including instructions which implement the function/act specified in the block(s) of the flowchart illustrations and/or block diagrams.

The computer program instructions may also be loaded onto a computer, other programmable data processing apparatus, or other device to cause a series of operational steps to be performed on the computer, other programmable apparatus or other device to produce a computer implemented process such that the instructions which execute on the computer, other programmable data processing apparatus, or other device provide processes for implementing the functions/acts specified in the block(s) of the flowchart illustrations and/or block diagrams.

The flowchart illustrations and block diagrams in the Figures illustrate the architecture, functionality, and operation of possible implementations of systems, methods, and computer program products according to various embodiments. In this regard, each block in the flowchart illustrations or block diagrams may represent a module, segment, or portion of code, which comprises one or more executable instructions for implementing the specified logical function(s). It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

In view of the foregoing, the scope of the present disclosure is determined by the claims that follow.

1. A method comprising:
measuring a galvanic current between a first component and a second component in a liquid cooling system;
determining, based on the galvanic current and a corrosion model for the liquid cooling system, a reverse bias voltage to prevent corrosion in the liquid cooling system; and
applying the reverse bias voltage in the liquid cooling system.

2. The method of claim 1,
wherein the first component comprises a copper heat exchanger,
wherein the second component comprises an aluminum heat exchanger,
wherein a negative electrode associated with the reverse bias voltage is connected to the aluminum heat exchanger, and
wherein a positive electrode associated with the reverse bias voltage is connected to the copper heat exchanger.

3. The method of claim 1, wherein the corrosion model comprises:
a coolant equivalent resistance for a liquid in the liquid cooling system, and historically applied reverse biases in the liquid cooling system.

4. The method of claim 3, wherein determining the reverse bias voltage comprises:
determining the reverse bias voltage based on the coolant equivalent resistance, wherein the reverse bias voltage comprises a voltage to counteract the galvanic current; and
updating the reverse bias voltage based on the historically applied reverse biases.

5. The method of claim 4, wherein applying the reverse bias voltage in the liquid cooling system comprises:
applying the reverse bias voltage via electrical contacts in the liquid cooling system, wherein the applied bias voltage reduces the galvanic current to prevent corrosion in the liquid cooling system.

6. The method of claim 1, further comprises:
measuring an updated galvanic current under reverse bias conditions in the liquid cooling system;
comparing the updated galvanic current to a corrosion threshold; and
when the galvanic current is above a corrosion threshold, updating the reverse bias voltage applied in the liquid cooling system, wherein the corrosion threshold comprises 1 microampere.

7. The method of claim 1, further comprising:
updating the corrosion model for the liquid cooling system with an indication of the galvanic current, the reverse bias voltage, and a time of reverse bias application; and
monitoring the galvanic current and a corrosion level in the liquid cooling system.

8. A system comprising:
a processor; and
a memory comprising instructions which, when executed on the processor, performs an operation, the operation comprising:
measuring a galvanic current between a first component and a second component in a liquid cooling system;
determining, based on the galvanic current and a corrosion model for the liquid cooling system, a reverse bias voltage to prevent corrosion in the liquid cooling system; and
applying the reverse bias voltage in the liquid cooling system.

9. The system of claim 8,
wherein the first component comprises a copper heat exchanger,
wherein the second component comprises an aluminum heat exchanger,
wherein a negative electrode associated with the reverse bias voltage is connected to the aluminum heat exchanger, and
wherein a positive electrode associated with the reverse bias voltage is connected to the copper heat exchanger.

10. The system of claim 8, wherein the corrosion model comprises:
a coolant equivalent resistance for a liquid in the liquid cooling system, and historically applied reverse biases in the liquid cooling system.

11. The system of claim 10, wherein determining the reverse bias voltage comprises:
determining the reverse bias voltage based on the coolant equivalent resistance, wherein the reverse bias voltage comprises a voltage to counteract the galvanic current; and
updating the reverse bias voltage based on the historically applied reverse biases.

12. The system of claim 11, wherein applying the reverse bias voltage in the liquid cooling system comprises:
applying the reverse bias voltage via electrical contacts in the liquid cooling system, wherein the applied bias voltage reduces the galvanic current to prevent corrosion in the liquid cooling system.

13. The system of claim 8, further comprises:
measuring an updated galvanic current under reverse bias conditions in the liquid cooling system;
comparing the updated galvanic current to a corrosion threshold; and
when the galvanic current is above a corrosion threshold, updating the reverse bias voltage applied in the liquid cooling system, wherein the corrosion threshold comprises 1 microampere.

14. The system of claim 8, further comprising:
updating the corrosion model for the liquid cooling system with an indication of the galvanic current, the reverse bias voltage, and a time of reverse bias application; and
monitoring the galvanic current and a corrosion level in the liquid cooling system.

15. A liquid cooling system comprising:
a first heat exchange component of a first material;
a second heat exchange component of a second material;
a first pipe between the first heat exchange component and the second heat exchange component;
a first electrical contact on a first end of the first pipe;
a second electrical contact on a second end of the first pipe; and
a reverse bias system, the reverse bias system comprising:
an external bias circuit electrically connected to the first electrical contact and the second electrical contact
a processor; and
a memory comprising instructions which, when executed on the processor, performs an operation, the operation comprising:
measuring a galvanic current between the first electrical contact and the second electrical contact;
determining, based on the galvanic current and a corrosion model for the liquid cooling system of the liquid cooling system, a reverse bias voltage to prevent corrosion in the liquid cooling system; and
applying the reverse bias voltage via the external bias circuit.

16. The liquid cooling system of claim 15,
wherein the first heat exchange component comprises an air cooled aluminum radiator,
wherein the second heat exchange component comprises a copper cold plate positioned on an electronic device,
wherein a negative electrode of the external bias circuit is connected to the first electrical contact, wherein the first electrical contact is connected to the air cooled aluminum radiator, and
wherein a positive electrode of the external bias circuit is connected to second electrical contact, wherein the second electrical contact is connected to the copper cold plate.

17. The liquid cooling system of claim 16, wherein the liquid cooling system further comprises:
a coolant pump system; and
a second pipe between the coolant pump system and the copper cold plate, wherein the coolant pump system pumps cooled coolant from the coolant pump system to the copper cold plate via the second pipe, and wherein heated coolant flows from the copper cold plate to the air cooled aluminum radiator.

18. The liquid cooling system of claim 15,
wherein the first heat exchange component comprises an air cooled aluminum radiator, and
wherein the second heat exchange component comprises a cooling system comprising:
a supply manifold;
a return manifold; and
a plurality of copper cold plates positioned between the supply manifold and the return manifold; and
wherein a negative electrode of the external bias circuit is connected to the first electrical contact, and
wherein a positive electrode of the external bias circuit is connected to second electrical contact, wherein the second electrical contact is connected to the supply manifold.

19. The liquid cooling system of claim 15,
wherein the corrosion model comprises:
a coolant equivalent resistance for a liquid in the liquid cooling system, and
historically applied reverse biases in the liquid cooling system; and
wherein determining the reverse bias voltage comprises:
determining the reverse bias voltage based on the coolant equivalent resistance, wherein the reverse bias voltage comprises a voltage to counteract the galvanic current; and
updating the reverse bias voltage based on the historically applied reverse biases; and
wherein applying the reverse bias voltage in the liquid cooling system comprises:
applying the reverse bias voltage via the first electrical contact and the second electrical contact, wherein the applied bias voltage reduces the galvanic current to prevent corrosion in the liquid cooling system.

20. The liquid cooling system of claim 15, wherein the operation further comprises:
measuring an updated galvanic current under reverse bias conditions in the liquid cooling system;
comparing the updated galvanic current to a corrosion threshold; and
when the galvanic current is above a corrosion threshold, updating the reverse bias voltage applied in the liquid cooling system, wherein the corrosion threshold comprises 1 microampere.
